(19) United States
(12) Patent Application Publication
(10) Pub. No.: US 2015/0049318 A1
(43) Pub. Date: Feb. 19, 2015

(54) OPTICAL ELEMENT, OPTICAL SYSTEM, CAPTURING APPARATUS, OPTICAL EQUIPMENT, AND ORIGINAL RECORDING AND MANUFACTURING METHOD THEREFOR

(71) Applicant: Sony Corporation, Tokyo (JP)

(72) Inventors: Kazuya Hayashibe, Kanagawa (JP); Masamitsu Kageyama, Kanagawa (JP); Tokihisa Kaneguchi, Kanagawa (JP)

(73) Assignee: Sony Corporation, Tokyo (JP)

(21) Appl. No.: 14/456,625

(22) Filed: Aug. 11, 2014

(30) Foreign Application Priority Data
Aug. 19, 2013 (JP) 2013-169741

(51) Int. Cl. G02B 1/12; G03F 1/00; G02B 3/00; G03F 7/20

(52) U.S. Cl. CPC G02B 1/12; G03F 7/70308; G03F 1/00; G02B 3/00
USPC 355/67; 430/5; 216/26

(57) ABSTRACT

An optical element includes a surface on which a plurality of structures is provided. The plurality of structures is provided to be fluctuated in a random direction from a lattice point at an interval which is equal to or shorter than a wavelength of visible light.

### CROSS REFERENCE TO RELATED APPLICATIONS

This application claims the benefit of Japanese Priority Patent Application JP 2013-169741 filed Aug. 19, 2013, the entire contents of which are incorporated herein by reference.

### BACKGROUND

The present technology relates to an optical element which has a plurality of structures on a surface thereof, an optical system, a capturing apparatus, an optical equipment, and an original recording and manufacturing method therefor.

In a technical field of the optical element, various technologies for suppressing surface reflection of light are used. One of the technologies is a technology for forming a sub-wavelength structure on an optical element surface (for an example, refer to “Optical Technology Contact”, Vol. 43, No. 11 (2005), 630-637).

In general, in a case where a periodic uneven shape is provided on the optical element surface, diffraction is generated when the light is transmitted therethrough, and a straight-advancing component of the transmitted light is substantially reduced. However, when a pitch of the uneven shape is shorter than a wavelength of the transmitted light, the diffraction is not generated, and it is possible to obtain an efficient anti-reflection effect.

The above-described anti-reflection technology is considered to be employed on various optical element surfaces in order to obtain excellent anti-reflection characteristics. For example, with reference to Japanese Unexamined Patent Application Publication No. 2011-002853, a technology for forming the sub-wavelength structure on a lens surface is suggested.

### SUMMARY

However, when an optical element (lens or the like) having a sub-wavelength structure formed on a surface thereof is used in an optical system, there is a case where diffraction light (stray light) is generated.

Therefore, it is desirable to provide an optical element which can suppress the generation of the diffraction light, an optical system, a capturing apparatus, an optical equipment, and an original recording and manufacturing method therefor.

According to an embodiment of the present technology, there is provided an optical element that includes a surface on which a plurality of structures is provided, and the plurality of structures is provided to be fluctuated in a random direction from a lattice point at an interval which is equal to or shorter than a wavelength of visible light.

According to another embodiment of the present technology, there is provided an original recording which includes a surface on which a plurality of structures is provided, and the plurality of structures is provided to be fluctuated in the random direction from the lattice point at the interval which is equal to or shorter than the wavelength of the visible light.

According to still another embodiment of the present technology, there is provided a manufacturing method for an original recording which includes: forming a plurality of exposure portions on a resist layer film-formed on the original recording, by using a plurality of masks in which a plurality of opening portions is provided to be fluctuated in the random direction from the lattice point; forming a resist pattern by developing the resist layer on which the plurality of the exposure portions are formed; and forming a surface on which the plurality of structures is provided at the interval which is equal to or shorter than the wavelength of the visible light, on the original recording, by performing an etching process with the resist pattern as the mask.

As described above, according to the present technology, it is possible to suppress the generation of the diffraction light.

### BRIEF DESCRIPTION OF THE DRAWINGS

FIGS. 1A to 1D are schematic views for describing an exposure pattern forming method by using multiple exposure;

FIG. 2A is a plan view illustrating an optical element surface on which a plurality of structures is provided at an ideal position, and FIG. 2B is a cross-sectional view for describing an operation of an optical element having the surface illustrated in FIG. 2A;

FIG. 3A is a plan view illustrating the optical element surface on which the plurality of structures is provided to be deviated from the ideal position, and FIG. 3B is a cross-sectional view illustrating an operation of an optical element having the surface illustrated in FIG. 3A;

FIG. 4A is a plan view illustrating an example of a configuration of the optical element according to a first embodiment of the present technology, FIG. 4B is a plan view showing an enlarged part of the optical element illustrated in FIG. 4A, and FIG. 4C is a cross-sectional view taken along line IVC-IVC of FIG. 4B;

FIG. 5 is a plan view showing an enlarged tetragonal lattice illustrated in FIG. 4B;

FIG. 6 is a cross-sectional view for describing the operation of the optical element according to the first embodiment of the present technology;

FIG. 7 is a plan view for describing an example of a configuration of an original recording according to the first embodiment of the present technology;

FIG. 8A is a plan view showing an enlarged part of the original recording illustrated in FIG. 7, and FIG. 8B is a cross-sectional view taken along line VIIIB-VIIIB of FIG. 8A;

FIGS. 9A to 9D are plan views for respectively describing an example of the configuration of a first to a fourth reticle;

FIG. 10 is a plan view showing an enlarged tetragonal lattice illustrated in FIG. 9A;

FIGS. 11A to 11D are cross-sectional views for describing an example of an optical element manufacturing method according to the first embodiment of the present technology;

FIGS. 12A to 12C are cross-sectional views for describing an example of the optical element manufacturing method according to the first embodiment of the present technology;

FIG. 13 is a plan view illustrating an example of an exposure pattern;

FIG. 14 is a plan view illustrating an example of a configuration of an optical element according to a second embodiment of the present technology;

FIGS. 15A to 15D are plan views for respectively describing an example of the configuration of the first to the fourth reticle;

FIG. 16 is a plan view illustrating an example of the exposure pattern;

FIG. 17 is a plan view illustrating an example of a configuration of an optical element according to a third embodiment of the present technology;

FIGS. 18A to 18C are plan views for respectively describing an example of the configuration of the first to the third reticle;

FIG. 19 is a plan view illustrating an example of the exposure pattern;

FIG. 20A is a schematic view illustrating an example of a configuration of a capturing apparatus according to a fourth embodiment of the present technology, and FIG. 20B is a schematic cross-sectional view illustrating an example of a configuration of a package of an image sensor element;

FIG. 21 is a schematic view illustrating an example of a configuration of a capturing apparatus according to a fifth embodiment of the present technology;

FIGS. 22A to 22C are views illustrating an evaluation results of a diffraction spot of the optical element, according to Embodiment 1, Comparative Example 1, and Reference Example 1, respectively; and

FIGS. 23A and 23B are views illustrating a diffraction spot cross-sectional light intensity of the optical element, according to Embodiment 1 and Comparative Example 1, respectively.

### DETAILED DESCRIPTION OF EMBODIMENTS

The present technology is appropriate to be employed in an optical element having a sub-wavelength structure formed on a surface thereof, an optical system which includes the optical element, and a capturing apparatus or an optical equipment which includes the optical element or the optical system. The present technology is appropriate to be employed even in an electronic device which includes the capturing apparatus. Examples of the optical element include a lens, a filter, a semi-transmissive mirror, a dimmer element, a prism, or a polarizing element, but the examples are not limited thereto. Examples of the capturing apparatus include a digital camera or a digital video camera, but the examples are not limited thereto. Examples of the optical equipment include a telescope, a microscope, an exposure device, a measuring device, a inspection device, or an analysis equipment, but the examples are not limited thereto.

Outline

The optical element having a plurality of structures provided on the surface thereof at an interval which is equal to or shorter than a wavelength of visible light, is generally formed by transferring an uneven shape of an original recording to a resin material. The uneven shape of the original recording is formed by combining a photolithography technology and an etching technology. As the photolithography technology, a technology for forming an exposure pattern on a resist layer of a surface of the original recording in steps and repeating by using a reticle (photomask), is used.

However, recently, it is desirable that a pitch of the structures on the optical element surface be narrow, and that a density of the structures be improved. In order to meet the desire, one example of the embodiment of the technology is an exposure pattern forming method by using multiple exposure.

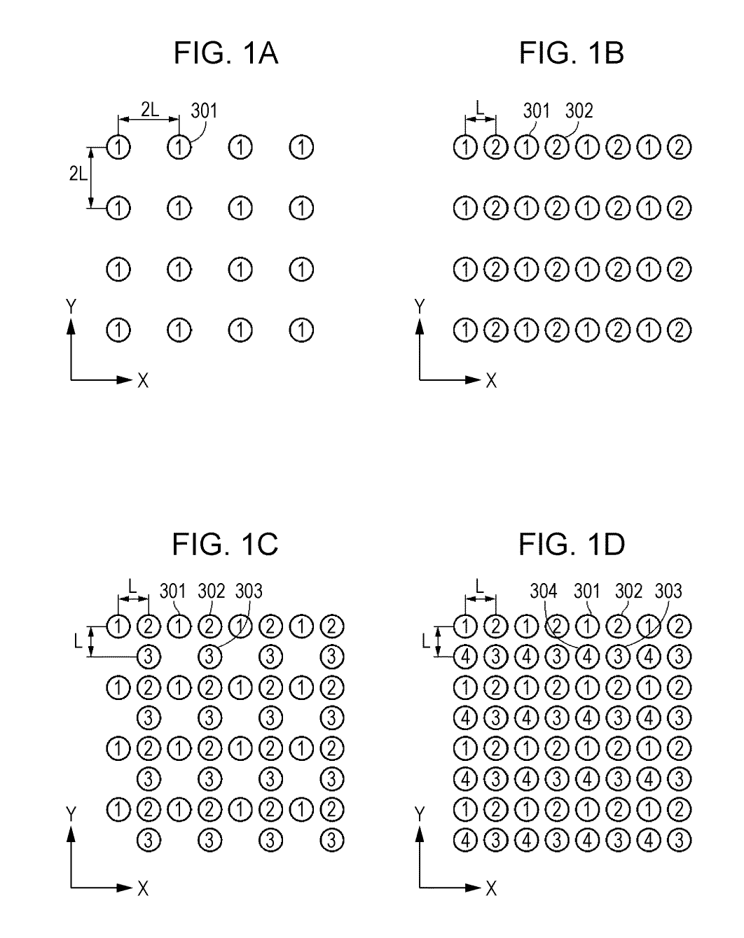

Here, with reference to FIGS. 1A to 1D, the exposure pattern forming method by using the multiple exposure will be described. As the reticle for forming the exposure pattern, four types of reticles having an arrangement pitch two times higher than an arrangement pitch of the structures formed on the optical element surface, are used.

First, by using a first reticle, as illustrated in FIG. 1A, a plurality of first exposure portions (exposure portion illustrated as No. 1 in FIGS. 1A to 1D) 301 is formed in a tetragonal lattice shape so that a distance between the adjacent exposure portions is 2 L.

Next, by using a second reticle instead of the first reticle, as illustrated in FIG. 1B, second exposure portions (exposure portion illustrated as No. 2 in FIGS. 1B to 1D) 302 are formed at positions deviated by a distance L in an X-axis direction from positions of each first exposure portion 301.

Next, by using a third reticle instead of the second reticle, as illustrated in FIG. 1C, third exposure portions (exposure portion illustrated as No. 3 in FIGS. 1C to 1D) 303 are formed at positions deviated by the distance L in the X-axis direction and at positions deviated by the distance L in a Y-axis direction, from positions of each first exposure portion 301.

Next, by using a fourth reticle instead of the third reticle, as illustrated in FIG. 1D, fourth exposure portions (exposure portion illustrated as No. 4 in FIG. 1D) 304 are formed at positions deviated by the distance L in the Y-axis direction from positions of each first exposure portion 301.

Accordingly, the exposure pattern made of the first exposure portion 301 to the fourth exposure portion 304 is formed on the resist layer. In the specification, by using the plurality of reticles, the exposure pattern is formed a plurality of times, and an exposure method for finally obtaining a desirable exposure pattern is referred to as “multiple exposure.”

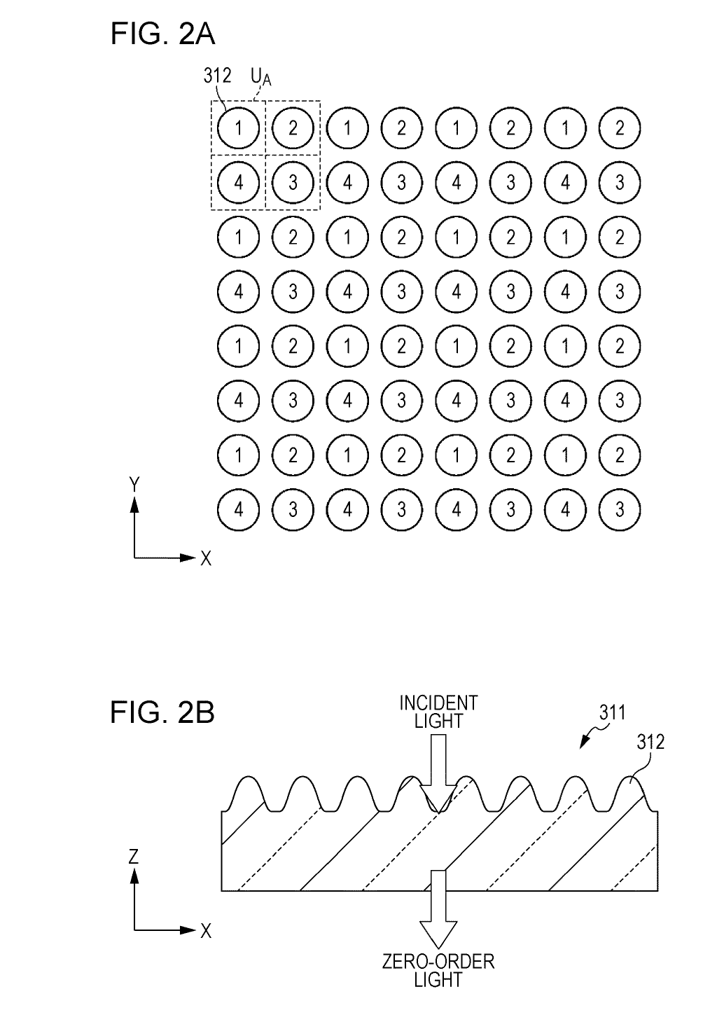

On a finally manufactured optical element surface as illustrated in FIGS. 2A and 2B, a regular pattern of a plurality of structures 312 is formed, corresponding to the exposure pattern. In addition, in FIG. 2A, No. 1 to No. 4 assigned in the structures 312 respectively illustrate a corresponding relationship between the first exposure portion 301 to the fourth exposure portion 304. If light is incident on an optical element 311 which has an ideal anti-reflection surface, as illustrated in FIG. 2B, diffraction light (±first-order diffraction light) is not generated, and only transmitted light (zero-order diffraction light) is generated.

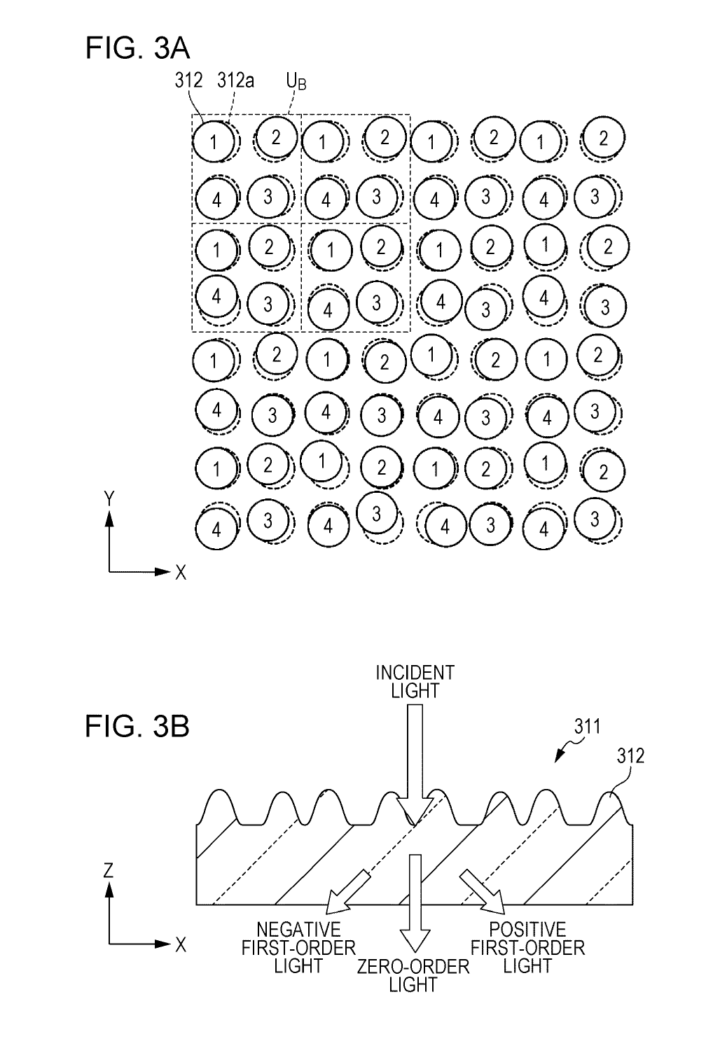

However, according to the view of the inventors, in a case of the multiple exposure, there is a case where a positional accuracy error (alignment error) is generated in the first to the fourth reticle, and a formation position of the exposure pattern is deviated from an ideal formation position. When the deviation of an exposure position is generated, as illustrated in FIG. 3A, the finally obtained position of each structure 312 of the optical element 311 is also deviated. In addition, in a case of the multiple exposure, circles 312a shown as a dashed line in FIG. 3A illustrate the formation positions of the structures when it is assumed that the positional accuracy error (alignment error) is not generated in the first to the fourth reticle. When the deviation of the positions of each structure 312 is generated as described above, a basic unit of a periodic structure of the structures 312 becomes larger, as much as the number of times(4 times in an example in which the first to the fourth reticle are used) of exposure, and a structure period becomes longer.

More specifically, in an ideal state where the positional accuracy error in the reticles is not generated, as illustrated in FIG. 2A, one structure 312 surrounded by a chain line is a unit structure U_{A}, and the unit structure U_{A} is periodically repeated in the X-axis direction and in the Y-axis direction. Meanwhile, in a real state where the positional accuracy error in the reticles is generated, as illustrated in FIG. 3A, four structures 312 surrounded by a chain line are a unit structure U_{B}, and the unit structure U_{B} is periodically repeated in the X-axis direction and in the Y-axis direction. Here, the unit structure U_{B} illustrated in FIG. 3A is four times larger than the unit structure U_{A} illustrated in FIG. 2A.

As described above, when the basic unit of the periodic structure becomes larger, and when the light is incident on an anti-reflection surface on which the structure period becomes longer, as illustrated in FIG. 3B, the diffraction light (±first-order diffraction light) is generated. When the optical element 311 is employed in the optical system, stray light, such as a diffraction spot, is generated.

Here, the inventors performed earnest investigation to suppress the generation of the diffraction light (stray light). As a result, the inventors found out that, by applying spatially random fluctuation to each opening portion of the plurality of reticles for use in exposure, the random fluctuation is generated even to alignment positions of each structure on the optical element surface, and thus the generation of the stray light is suppressed.

An embodiment of the present technology will be described in the following order with reference to the drawings.

1 First Embodiment (Example in which each structure is provided to be fluctuated from a lattice point of a tetragonal lattice)

1.1 Configuration of Optical Element

1.2 Operation of Optical Element

1.3 Configuration of Original Recording

1.4 Configuration of Reticle

1.5 Manufacturing Method for Optical Element

1.6 Effect

2 Second Embodiment (Example in which each structure is provided to be fluctuated from a lattice point of a rectangular lattice)

2.1 Configuration of Optical Element

2.2 Configuration of Reticle

2.3 Manufacturing Method for Optical Element

3 Third Embodiment (Example in which each structure is provided to be fluctuated from a lattice point of a hexagonal lattice)

3.1 Configuration of Optical Element

3.2 Configuration of Reticle

3.3 Manufacturing Method for Optical Element

4 Fourth Embodiment (Example in which the optical element is employed in a digital camera)

4.1 Outline

4.2 Configuration of Capturing Apparatus

4.3 Effect

5 Fifth Embodiment (Example in which the optical element is employed in a digital video camera)

5.1 Outline

5.2 Configuration of Capturing Apparatus

5.3 Effect

### 1 First Embodiment

1.1 Configuration of Optical Element

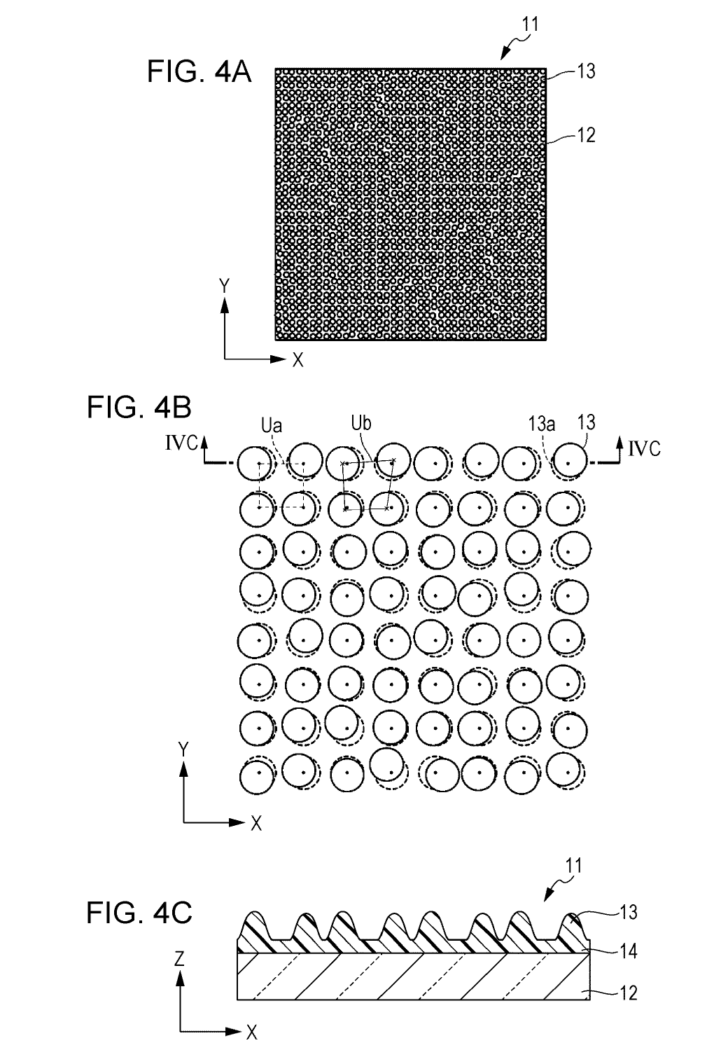

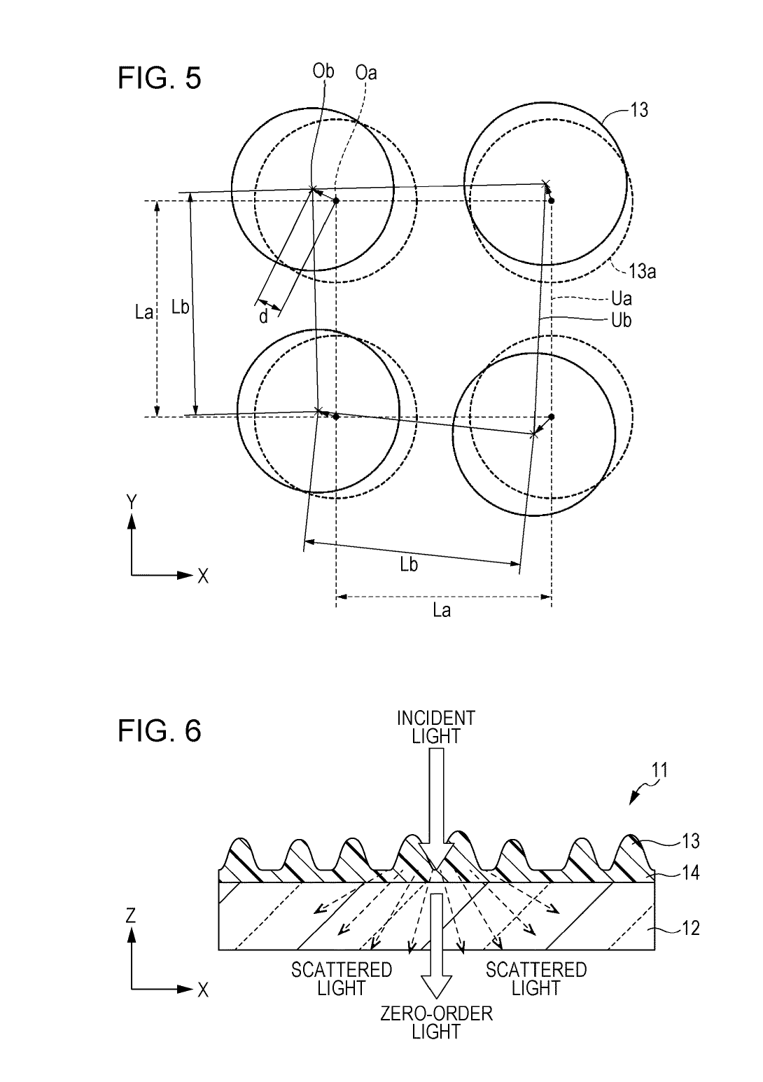

Hereinafter, with reference to FIGS. 4A to 4C and FIG. 5, an example of a configuration of an optical element 11 will be described. As described in FIGS. 4A to 4C, the optical element 11 includes a base 12 having a surface and a plurality of structures 13 provided on the surface of the base 12. The structure 13 and the base 12 are separately or integrally formed. When the structure 13 and the base 12 are separately formed, an intermediate layer 14 may be further provided between the structure 13 and the base 12 when necessary. The intermediate layer 14 is a layer which is integrally formed with the structure 13 on a bottom surface side of the structure 13, and is configured to be made of the same material as the structure 13. Here, two directions which are orthogonal to each other on the surface of the optical element 11 are referred to as the X-axis direction (first direction) and the Y-axis direction (second direction), respectively. A direction which is perpendicular to the surface (XY planar surface) is referred to as a Z-axis direction (third direction).

Hereinafter, the base 12 provided in the optical element 11 and the structure 13 will be described in order.

Base

The base 12 has transparency. A material of the base 12 may be a material having transparency, and may be any of an organic material or an inorganic material. Examples of the material of an inorganic base include quartz, sapphire, or glass. Examples of the organic material can generally include a polymer material. Specifically, examples of the general polymer material include triacetylcellulose (TAC), polyester (TPEE), polyethylene terephthalate (PET), polyethylene naphthalate (PEN), polyimide (PI), polyamide (PA), aramid, polyethylene (PE), polyacrylate, polyethersulfone, polysulfone, polypropylene (PP), diacetyl cellulose, polyvinyl chloride, acrylic resin (PMMA), polycarbonate (PC), epoxy resin, urea resin, urethane resin, melamine resin, cycloolefin polymer (COP), or cycloolefin copolymer.

When the organic material is used as the material of the base 12, in order to improve surface energy, coating property, slipping property, and flatness of the surface of the base 12, an undercoat layer may be provided as a surface treatment. Examples of a material of the undercoat layer include organoalkoxy metal compound, polyester, acrylic modified polyester, or polyurethane. In addition, in order to obtain the same effect as a case where the undercoat layer is provided, the surface treatment, such as corona discharge or UV irradiation treatment, may be performed with respect to the surface of the base 12.

Examples of a shape of the base 12 can include a film shape, a board shape, or a block shape, but the shape is not particularly limited thereto. Here, the film shape is defined to include a sheet shape. A thickness of the base 12 is approximately 25 μm to 500 μm, for example. When the base 12 is a plastic film, the base 12 can be obtained by a method of film-forming in a film shape and drying after stretching the above-described resin or diluting a solvent, for example. The base 12 may be a component, such as a member or an equipment, which is an application target of the optical element 11.

The surface of the base 12 is not limited to a planar surface, and may be an uneven surface, a polygonal surface, a curved surface, or a surface combined by these. Examples of the curved surface include a partial spherical surface, a partial ellipsoidal surface, a partial parabolic surface, or a free-form curved surface. Here, the partial spherical surface, the partial ellipsoidal surface, and the partial parabolic surface represent a surface of a part of a sphere, an ellipsoid, and a paraboloid, respectively.

In addition, in FIG. 4A, an example is described in which a shape of the surface of the base 12 when viewed from the Z-axis direction is a rectangular shape. However, the surface shape of the base 12 is not limited to the rectangular shape, and can be selected according to a surface shape of the member or the equipment in which the optical element 11 is employed.

Structure

The structure 13 is a so-called sub-wavelength structure. The structure 13 has a protruded shape with respect to the surface of the base 12. As shown in FIG. 5, the plurality of the structures 13 is provided to be fluctuated in a random direction from a lattice point Oa of a tetragonal lattice Ua, at an interval Lb which is equal to or shorter than a wavelength band of the light for reducing the reflection. In other words, the plurality of structures 13 is disposed on each lattice point Ob of a distorted tetragonal lattice Ub. A distortion direction of each distorted tetragonal lattice Ub is random. In addition, in FIG. 4B and FIG. 5, each structure 13a shown as a dashed line illustrates virtual structures disposed on each lattice point Oa of the tetragonal lattice Ua.

Here, the wavelength band of the light for reducing the reflection is, for example, a wavelength band of ultraviolet light, the visible light, or infrared light. The wavelength band of the ultraviolet light is 10 nm to 360 nm, the wavelength band of the visible light is 360 nm to 830 nm, and the wavelength band of the infrared light is 830 nm to 1 mm. In addition, the distorted tetragonal lattice Ub represents a tetragonal lattice Ua to which distortion is applied.

Each lattice point Oa is aligned at the same lattice interval La in the X-axis and Y-axis directions. Each lattice point Ob is aligned to be fluctuated in the random direction from the lattice point Oa, at the random lattice interval Lb. In addition, in FIG. 5, the direction of the fluctuation of the lattice point Oa is illustrated as an arrow. The center of the structure 13 and the lattice point Ob match each other, and thus the plurality of structures 13 is provided on the surface of the base 12. Therefore, the interval between the adjacent lattice points Ob and the interval between the centers of the adjacent structures 13 are the same.

It is preferable that a fluctuation width d (that is, a fluctuation width of the center position of the structure 13 of which a standard is the lattice point Oa) of the lattice point Ob of which the standard is the lattice point Oa be equal to or less than half of the distance La (equal to or less than La/2) between the adjacent lattice points Oa. This is because it is possible to suppress deterioration of anti-reflection characteristics of the optical element 11. Here, the positions of each lattice point Oa of the tetragonal lattice Ua are virtual positions obtained by averaging the positions of the plurality of lattice points Ob of the distorted tetragonal lattice Ub. In addition, the fluctuation direction is an in-surface direction (that is, an in-surface direction on an XY surface) of the surface of the base 12.

Examples of a specific shape of the structure 13 include a conical shape, a pillar shape, a needle shape, a hemispherical shape, a semi-elliptic shape, or a polygonal shape, but the shape is not limited thereto. Other shapes may be employed. Examples of the conical shape include a conical shape which has a pointed top, a conical shape which has a flat top, or a conical shape which has a protruded top or a recessed top with a curved surface, but the conical shape is not limited thereto. Examples of the conical shape which has the protruded top with a curved surface include a two-dimensional curved surface shape, such as a paraboloidal shape. A conical surface in a conical shape may be curved in a recessed shape or a protruded shape.

All of the plurality of structures 13 provided on the surface of the base 12 may have the same size, shape, and height. The plurality of structures 13 may have a different size, shape, and height. In addition, the plurality of structures 13 may be connected by overlapping lower portions thereof.

1.2 Operation of Optical Element

With reference to FIG. 6, an operation of the optical element 11 which has the above-described configuration will be described. When the light is incident on the surface where the plurality of structures 13 is provided, as illustrated in FIG. 6, the diffraction light (±first-order diffraction light) is not generated, and the transmitted light (zero-order diffraction light) and scattered light are generated. Therefore, the generation of the diffraction light (±first-order diffraction light) illustrated in FIG. 3B is suppressed. When the optical element 11 is employed in the optical system, the generation of the stray light, such as the diffraction spot, is suppressed.

1.3 Configuration of Original Recording

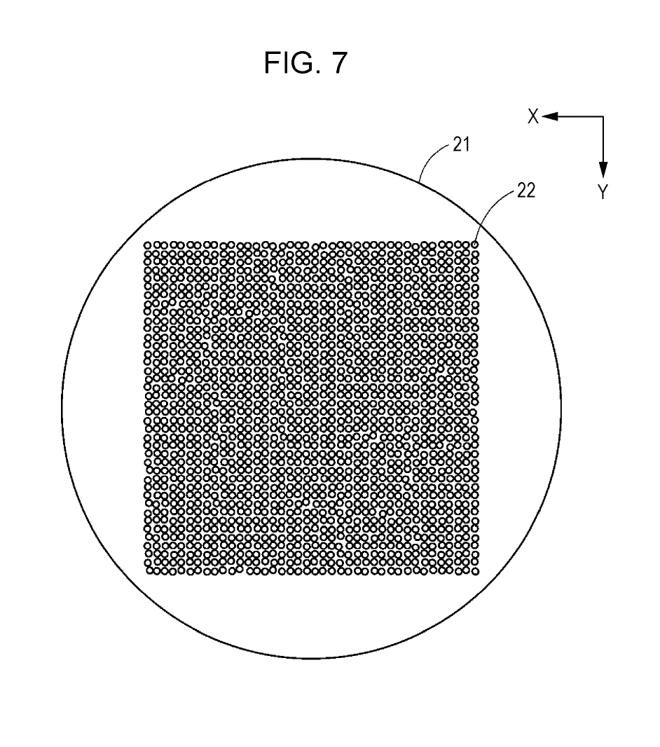

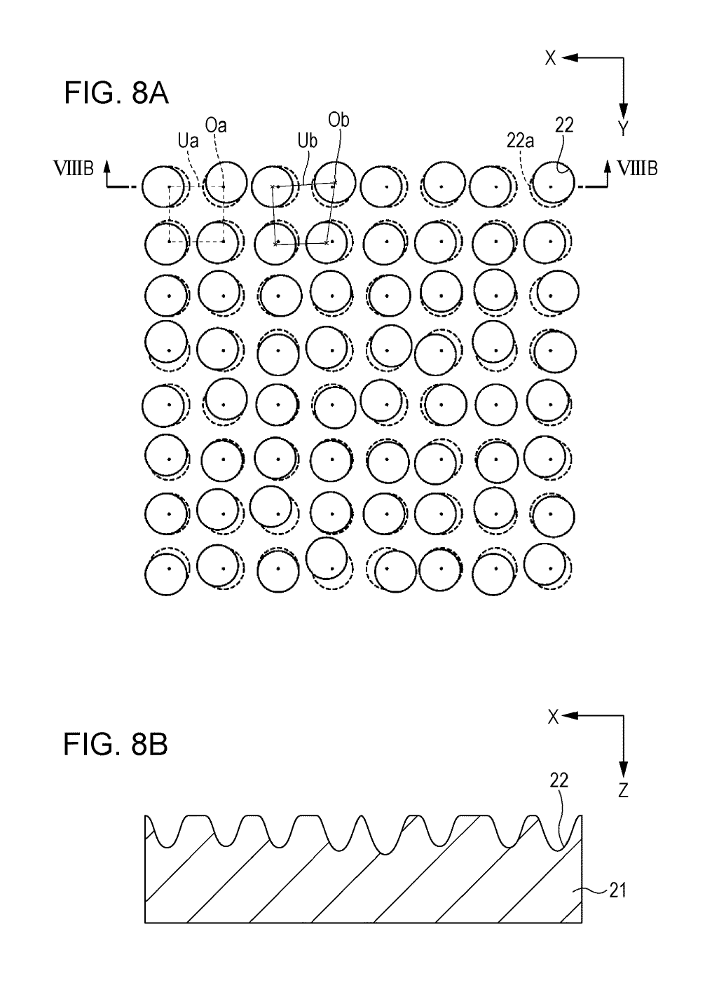

With reference to FIGS. 7, 8A, and 8B, an example of a configuration of an original recording 21 will be described. Here, two directions orthogonal to each other on the surface of the original recording 21 are referred to as the X-axis direction and the Y-axis direction, respectively. The direction perpendicular to the surface (XY planar surface) is referred to as the Z-axis direction.

The original recording 21 is an original recording for molding the plurality of structures 13 on the surface of the above-described base 12. The original recording 21 has, for example, a disk shape. One principal surface of the original recording 21 is a molding surface for molding the plurality of structures 13 on the surface of the base 12. On the molding surface, the plurality of the structures 22 is provided. The structure 22 has, for example, a recessed shape with respect to the molding surface. Examples of a material of the original recording 21 can include silicone or glass, but the material is not particularly limited thereto.

The plurality of structures 22 provided on the molding surface of the original recording 21 and the plurality of structures 13 provided on the surface of the above-described base 12 are in a reversed concavo-convex relationship. In other words, the arrangement and the shape of the structures 22 of the original recording 21 are the same as that of the structures 13 of the base 12. In addition, in FIG. 8A, the plurality of structures 22a shown as a dashed line illustrates the plurality of virtual structures disposed on the lattice point Oa of the tetragonal lattice Ua.

1.4 Configuration of Reticle

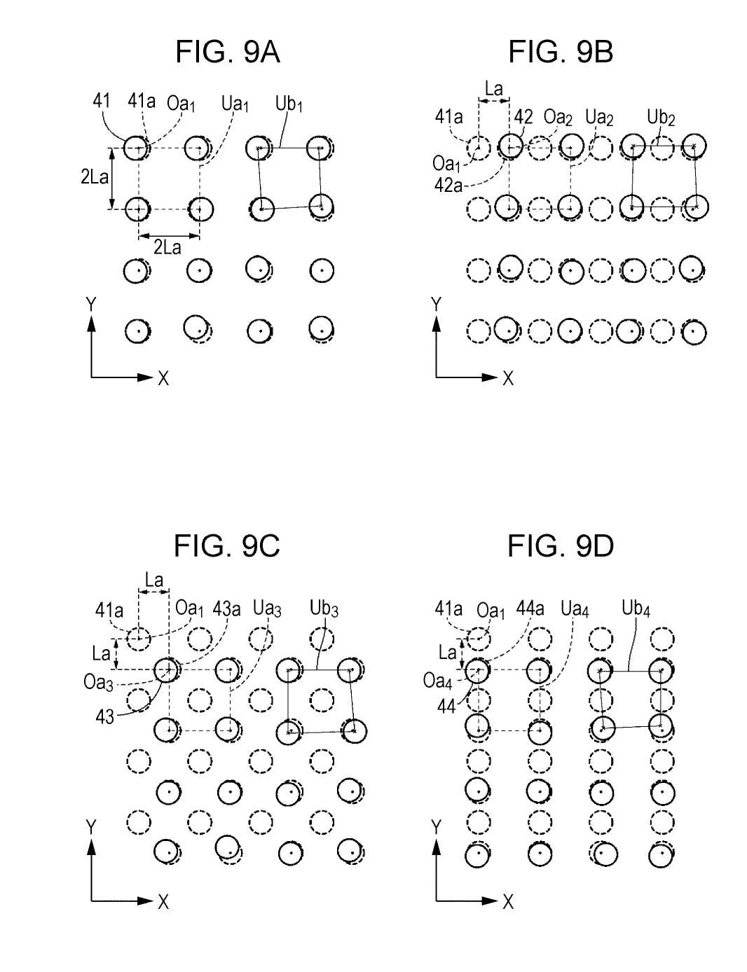

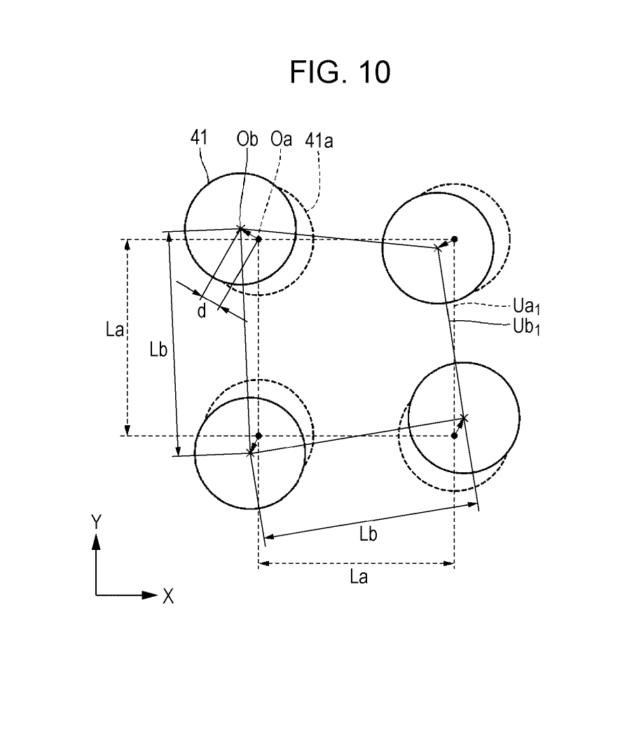

With reference to FIGS. 9A to 9D and FIG. 10, an example of a configuration of the first to the fourth reticle will be described. Here, two directions orthogonal to each other on the surface of the first to the fourth reticle are referred to as the X-axis direction and the Y-axis direction, respectively.

First Reticle

As illustrated in FIG. 9A and FIG. 10, the first reticle has a plurality of opening portions 41. The plurality of opening portions 41 is provided to be fluctuated in a random direction from a lattice point Oa₁ of a tetragonal lattice Ua₁, at the interval Lb which corresponds to substantially two times the lattice interval La of the optical element 11. In other words, the plurality of opening portions 41a is disposed on each lattice point Ob₁ of a distorted tetragonal lattice Ub₁, and the distortion direction of each distorted tetragonal lattice Ub₁ is random. In addition, in FIGS. 9A and 10, each opening portion 41a shown as a dashed line illustrates virtual opening portions disposed on each lattice point Oa₁ of the tetragonal lattice Ua₁.

Each lattice point Oa₁ is aligned at the same lattice interval 2La in the X-axis and Y-axis directions. Each lattice point Ob₁ is aligned to be fluctuated in the random direction from the lattice points Oa₁ at the random lattice interval Lb. In addition, in FIG. 10, the fluctuation direction of the lattice point Oa₁ is shown as an arrow. The center of the opening portion 41 and the lattice point Ob₁ match each other, and thus the plurality of opening portions 41 is provided on the first reticle. Therefore, the interval between the adjacent lattice points Ob₁ and the interval between the centers of the adjacent opening portions 41a are the same.

It is preferable that a fluctuation width d (that is, a fluctuation width of the center position of the opening portion 41a of which a standard is the lattice point Oa₁) of the lattice point Ob₁ of which the standard is the lattice point Oa₁ be equal to or less than half of the distance La (equal to or less than La/2) between the adjacent lattice points Oa. Here, the positions of each lattice point Oa₁ of the tetragonal lattice Ua₁ are virtual positions obtained by averaging the positions of the plurality of lattice points Ob₁ of the distorted tetragonal lattice Ub₁.

When an alignment accuracy of the reticles in a stepper is δ, it is preferable that the fluctuation width d of the lattice point Ob₁ of which the standard is the lattice point Oa₁ be larger than the alignment accuracy δ. This is because the effect of suppression of the generation of the diffraction light (±first-order diffraction light) is improved.

Second Reticle

As illustrated in FIG. 9B, other than having a plurality of opening portions 42 provided to be fluctuated in the random direction from each lattice point Oa₂, the second reticle has the same configuration as the first reticle. The lattice point Oa₂ is the lattice point of the tetragonal lattice Ua₂. The tetragonal lattice Ua₂ is the tetragonal lattice obtained by deviating each lattice point Oa₁ of the tetragonal lattice Ua₁ at the interval La in the X-axis direction.

Third Reticle

As illustrated in FIG. 9C, other than having a plurality of opening portions 43 provided to be fluctuated in the random direction from each lattice point Oa₃, the third reticle has the same configuration as the first reticle. The lattice point Oa₃ is the lattice point of the tetragonal lattice Ua₃. The tetragonal lattice Ua₃ is the tetragonal lattice obtained by deviating each lattice point Oa₁ of the tetragonal lattice Ua₁ at the interval La in the X-axis direction and at the interval La in the Y-axis direction.

Fourth Reticle

As illustrated in FIG. 9D, other than having a plurality of opening portions 44 provided to be fluctuated in the random direction from each lattice point Oa₄, the fourth reticle has the same configuration as the first reticle. The lattice point Oa₄ is the lattice point of the tetragonal lattice Ua₄. The tetragonal lattice Ua₄ is the tetragonal lattice obtained by deviating each lattice point Oa₁ of the tetragonal lattice Ua₁ at the interval La in the Y-axis direction.

1.5 Manufacturing Method for Optical Element

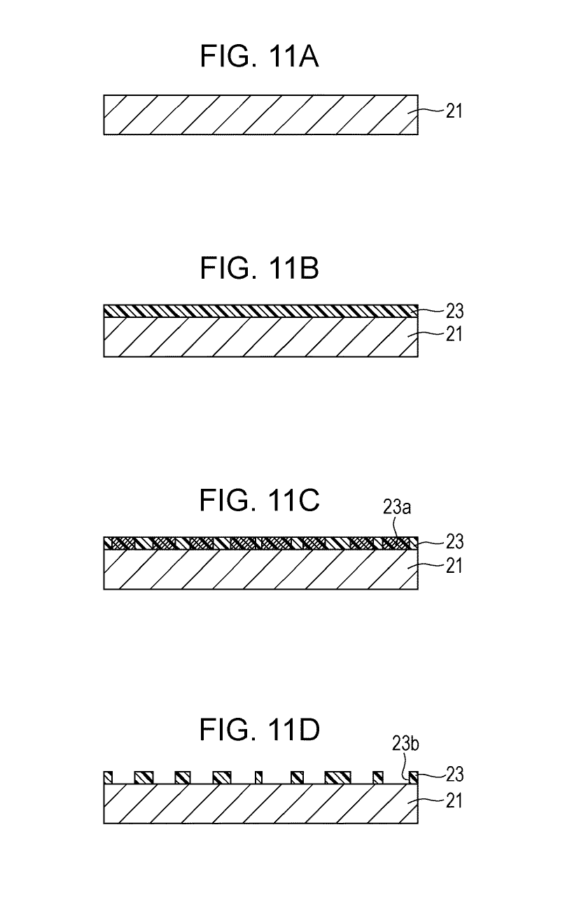

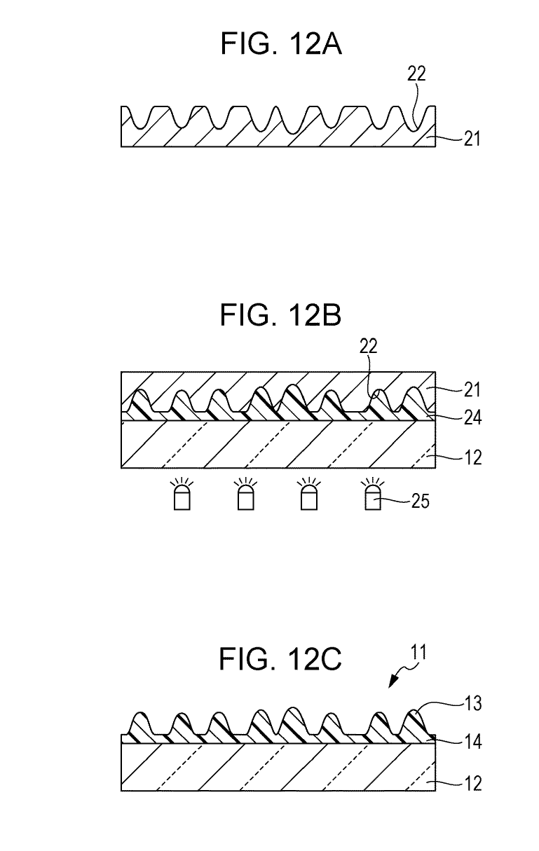

Next, with reference to FIGS. 11A to 12C, an example of the manufacturing method for the optical element 11 according to first embodiment of the present technology will be described.

Resist Film-Forming Process

First, as illustrated in FIG. 11A, the original recording 21, such as an original recording having a disk shape, is prepared. Next, as illustrated in FIG. 11B, a resist layer 23 is formed on the surface of the original recording 21. As a material of the resist layer 23, any of an organic resist or an inorganic resist may be used. As the organic resist, a novolac-based resist or a chemical amplification type resist can be used. In addition, as the inorganic resist, a metallic compound including one or more types of metal can be used.

Exposure Process

Next, as illustrated in FIG. 11C, a plurality of exposure portions (exposure pattern) 23a is formed on the resist layer 23 formed on the surface of the original recording 21. The plurality of exposure portions 23a is formed in steps and repeats by using the first to the fourth reticle.

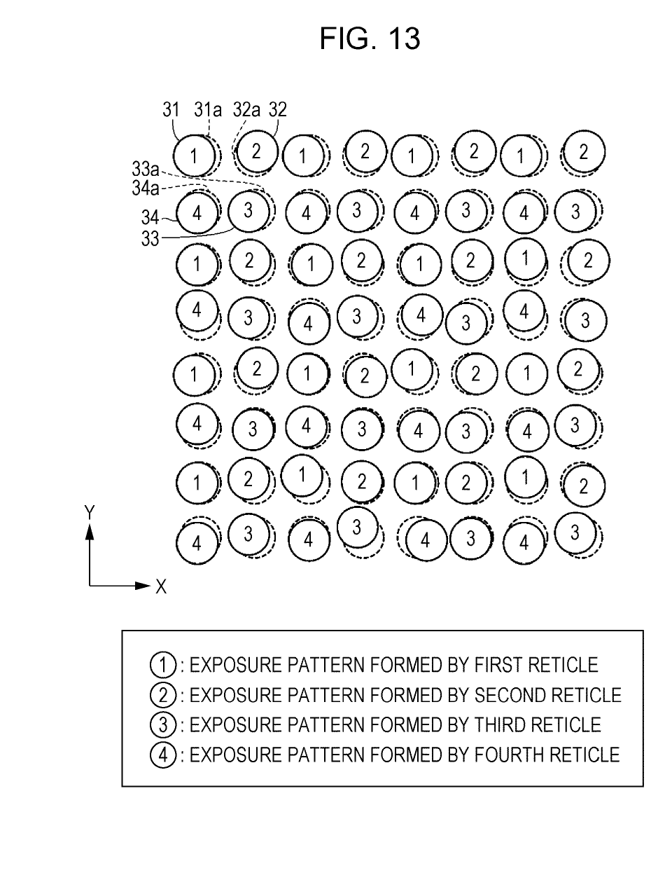

Here, with reference to FIGS. 9A to 9D and FIG. 13, an example of the exposure process will be described in detail. In addition, No. 1 to 4 described in FIG. 13 illustrate the following exposure pattern.

No. 1: Exposure pattern formed by the first reticle

No. 2: Exposure pattern formed by the second reticle

No. 3: Exposure pattern formed by the third reticle

No. 4: Exposure pattern formed by the fourth reticle

In addition, the first reticle having an opening pattern as illustrated in FIG. 9A is mounted on the stepper (not illustrated). Next, by using the first reticle, the resist layer 23 of the original recording 21 is light-exposed. Accordingly, as illustrated in FIG. 13, the plurality of exposure portions 31 is formed on the resist layer 23. In other words, the plurality of exposure portions 31 is formed to be fluctuated in the random direction from the lattice point of the tetragonal lattice at an interval corresponding to substantially two times the lattice interval La of the optical element 11. In addition, each circle 31a shown as a dashed line in FIG. 13 illustrates virtual exposure portions formed by each virtual opening portion 41a shown as a dashed line in FIG. 9A.

Next, the second reticle having an opening pattern as illustrated in FIG. 9B is mounted on the stepper (not illustrated). Next, by using the second reticle, the resist layer 23 of the original recording 21 is light-exposed. Accordingly, as illustrated in FIG. 13, the plurality of exposure portions 32 is formed on the resist layer 23. In other words, the plurality of exposure portions 32 is formed to be fluctuated in the random direction from the lattice point of the tetragonal lattice at an interval corresponding to substantially two times the lattice interval La of the optical element 11. In addition, each circle 32a shown as a dashed line in FIG. 13 illustrates virtual exposure portions formed by each virtual opening portion 42a shown as a dashed line in FIG. 9B.

Next, the third reticle having an opening pattern as illustrated in FIG. 9C is mounted on the stepper (not illustrated). Next, by using the third reticle, the resist layer 23 of the original recording 21 is light-exposed. Accordingly, as illustrated in FIG. 13, the plurality of exposure portions 33 is formed on the resist layer 23. In other words, the plurality of exposure portions 33 is formed to be fluctuated in the random direction from the lattice point of the tetragonal lattice at an interval corresponding to substantially two times the lattice interval La of the optical element 11. In addition, each circle 33a shown as a dashed line in FIG. 13 illustrates virtual exposure portions formed by each virtual opening portion 43a shown as a dashed line in FIG. 9C.

Next, the fourth reticle having an opening pattern as illustrated in FIG. 9D is mounted on the stepper (not illustrated). Next, by using the fourth reticle, the resist layer 23 of the original recording 21 is light-exposed. Accordingly, as illustrated in FIG. 13, the plurality of exposure portions 34 is formed on the resist layer 23. In other words, the plurality of exposure portions 34 is formed to be fluctuated in the random direction from the lattice point of the tetragonal lattice at an interval corresponding to substantially two times the lattice interval La of the optical element 11. In addition, each circle 34a shown as a dashed line in FIG. 13 illustrates virtual exposure portions formed by each virtual opening portion 44a shown as a dashed line in FIG. 9D.

According to the above exposure process, the exposure pattern made of the plurality of exposure portions 31 to 34 is formed on the resist layer 23. As illustrated in FIG. 13, the plurality of exposure portions 31 to 34 is formed to be fluctuated in the random direction from the lattice point of the tetragonal lattice, at the interval which is equal to or shorter than the wavelength band of the light for reducing the reflection of the optical element 11. In other words, the plurality of exposure portions 31 to 34 is disposed at each lattice point of the distorted tetragonal lattice, and the distortion direction of each distorted tetragonal lattice is random. In the example, a process using four types of reticle is described, but the number of the types of the reticle is not limited thereto. For example, two types of reticle may be used.

Development Process

Next, for example, while the original recording 21 is rotated, the resist layer 23 is developed by dropping a developer onto the resist layer 23. Accordingly, as illustrated in 11D, the plurality of opening portions 23b is formed on the resist layer 23. When the resist layer 23 is formed by a positive type resist, since a dissolution rate of the exposure portion increases with respect to the developer compared to a non-exposure portion, as illustrated in FIG. 11D, the pattern is formed on the resist layer 23 corresponding to the exposure portion (latent image) 23a.

Etching Process

Next, by using the pattern (resist pattern) of the resist layer 23 formed on the original recording 21 as a mask, the surface of the original recording 21 is etched. Accordingly, as illustrated in FIG. 12A, the plurality of structures 22 is formed on the surface of the original recording 21. For etching, any of dry etching and wet etching may be used. In the process, an etching processing and an ashing processing may be performed alternately. Accordingly, the shape of each structure 22 can be a conical shape.

According to the above, the targeted original recording 21 is obtained.

Transferring Process

Next, as illustrated in FIG. 12B, after adhering the original recording 21 to a transfer material 24 coated on the base 12, irradiating the transfer material 24 with an energy ray, such as an ultraviolet ray, from an energy ray source 25, and hardening the transfer material 24, the base 12 which is integrated with the hardened transfer material 24 is detached. Accordingly, as illustrated in FIG. 12C, an optical element 11 which has the plurality of structures 13 on a base surface is manufactured. Next, when necessary, the optical element 11 may be cut to a desirable size.

The energy ray source 25 may be any energy ray source which can discharge the energy ray, such as an electron beam, the ultraviolet ray, the infrared ray, a laser beam, a visible ray, an ionizing radiation (X ray, α ray, β ray, γ ray, or the like), a microwave, or a high frequency ray, and the energy ray is not particularly limited.

It is preferable that an energy ray curable resin composition be used as the transfer material 24. It is preferable that an ultraviolet ray curable resin composition be used as the energy ray curable resin composition. The energy ray curable resin composition may include a filler or a functional additive when necessary.

Examples of the ultraviolet ray curable resin composition include acrylate or an initiator. Examples of the ultraviolet ray curable resin composition include a monofunctional monomer, a bifunctional monomer, or a polyfunctional monomer, and more specifically, include the following materials independently or a mixture prepared by mixing plural kinds of the following materials.

Examples of the monofunctional monomer can include carboxylic acid (acrylic acid), hydroxyl (2-hydroxyethyl acrylate, 2-hydroxypropyl acrylate, 4-hydroxybutyl acrylate), alkyl, alicyclic compound (isobutyl acrylate, t-butyl acrylate, isooctyl acrylate, lauryl acrylate, stearyl acrylate, isobornyl acrylate, cyclohexyl acrylate), other functional monomer (2-methoxyethyl acrylate, methoxyethylene glycolacrylate, 2-ethoxyethyl acrylate, tetrahydrofurfuryl acrylate, benzyl acrylate, ethyl carbitol acrylate, phenoxyethyl acrylate, N,N-dimethylaminoethyl acrylate, N,N-dimethylaminopropyl acrylamide, N,N-dimethylacrylamide, acryloyl morpholine, N-isopropylacrylamide, N,N-diethyl acrylamide, N-vinyl pyrrolidone, 2-(perfluorooctyl)ethyl acrylate, 3-perfluorohexyl-2-hydroxypropyl acrylate, 3-perfluorooctyl-2-hydroxypropyl acrylate, 2-(perfluorodecyl)ethyl acrylate, 2-(perfluoro 3-methylbutyl)ethyl acrylate, 2,4,6-tribromophenol acrylate, 2,4,6-tribromophenol methacrylate, 2-(2,4,6-tribromo phenoxy)ethyl acrylate), or 2-ethylhexyl acrylate.

Examples of the bifunctional monomer can include tri(propylene glycol)diacrylate, trimethylolpropane diallyl ether, or urethane acrylate.

Examples of the polyfunctional monomer can include trimethylolpropane triacrylate, dipentaerythritol penta- and hexa-acrylate, or ditrimethylolpropane tetraacrylate.

Examples of the initiator include 2,2-dimethoxy-1,2-diphenylethan-1-one, 1-hydroxy-cyclohexylphenyl ketone, or 2-hydroxy-2-methyl-1-phenylpropan-1-one.

As the filler, any of inorganic fine particle and organic fine particle can be used. Examples of the inorganic fine particle include a metal oxide fine particle, such as, SiO₂, TiO₂, ZrO₂, SnO₂, or Al₂O₃.

Examples of the functional additive include a leveling agent, a surface conditioner, or a defoaming agent. Examples of the material of the base 12 include methyl methacrylate (co)polymer, polycarbonate, styrene (co)polymer, methyl methacrylate-styrene copolymer, cellulose diacetate, cellulose triacetate, cellulose acetate butyrate, polyester, polyamide, polyimide, polyethersulfone, polysulfone, polypropylene, polymethylpentene, polyvinyl chloride, polyvinyl acetal, polyether ketone, polyurethane, and glass.

The molding method for the base 12 is not particularly limited. The base 12 may be an injection molding body, an extrusion molding body, and a cast molding body. When necessary, the surface treatment, such as corona treatment, may be performed on the base surface.

According to the above, the targeted optical element 11 is obtained.

1.6 Effect

In the optical element 11 according to the first embodiment, since the plurality of structures 13 is provided to be fluctuated in the random direction from the lattice point at the interval equal to or shorter than the wavelength of the visible light, the diffraction light can be randomly scattered. Therefore, when the optical element 11 is employed in the optical system, the generation of the stray light can be suppressed.

The plurality of reticles (mask) is prepared by deviating the opening pattern in the random direction from the lattice point of the tetragonal lattice, and the multiple exposure is performed by deviating each reticle at the lattice interval. Accordingly, the original recording 21 for molding the above-described optical element 11 is manufactured.

### 2 Second Embodiment

2.1 Configuration of Optical Element

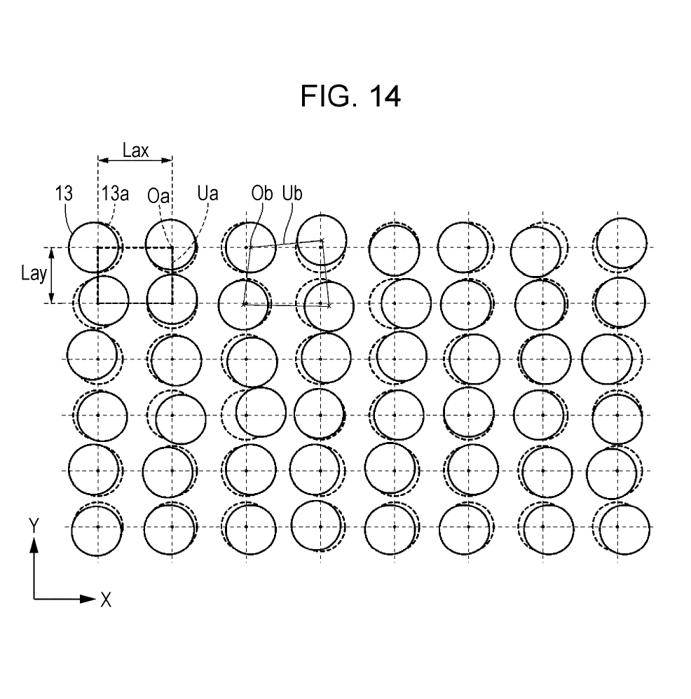

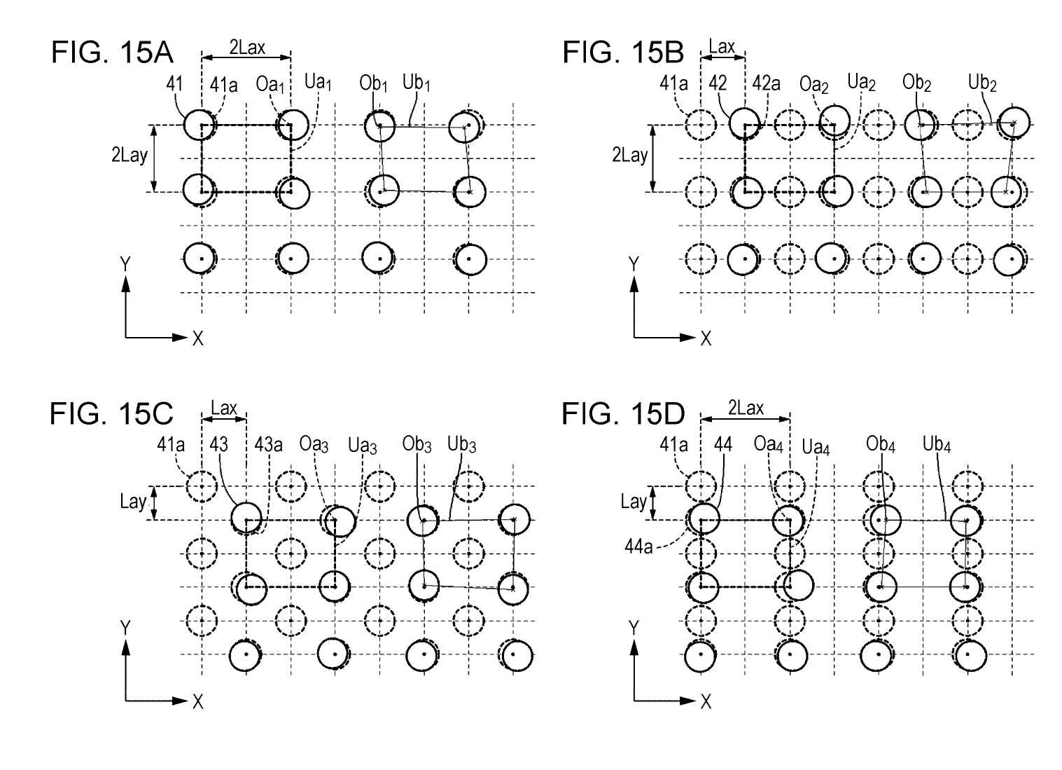

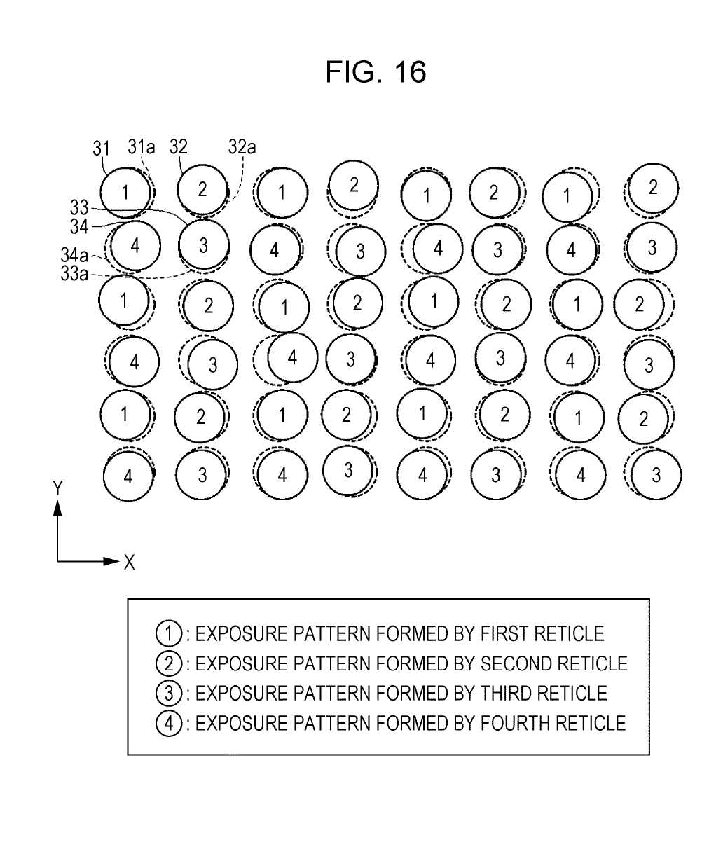

An optical element 11 according to the second embodiment of the present technology is different from the first embodiment, from the viewpoint that a rectangular lattice Ua illustrated in FIG. 14 is used instead of the tetragonal lattice Ua illustrated in FIG. 4B. The plurality of structures 13 is disposed on each lattice point Ob of the distorted tetragonal lattice Ub, and the distortion direction of each distorted rectangular lattice Ub is random.

2.2 Configuration of Reticle

A first to a fourth reticle used in the manufacturing method for the optical element 11 according to the second embodiment of the present technology are different from the first embodiment, from the viewpoint that rectangular lattices Ua₁ to Ua₄ illustrated in FIGS. 15A to 15D are used instead of the tetragonal lattices Ua₁ to Ua₄ illustrated in FIGS. 9A to 9D.

2.3 Manufacturing Method for Optical Element

In a manufacturing method for the optical element 11 according to the second embodiment of the present technology, by using the first to the fourth reticle which have the above-described configuration, a plurality of exposure portions 31 to 34 is formed in the order from No. 1 to 4 described in FIG. 14. In other words, the plurality of exposure portions 31 to 34 is formed to be fluctuated in the random direction from the lattice point of the rectangular lattice, at the interval which is equal to or shorter than the wavelength band of the light for reducing the reflection of the optical element 11. Therefore, the plurality of exposure portions 31 to 34 is disposed on each lattice point of the distorted rectangular lattice, and the distortion direction of each distorted tetragonal lattice is random.

### 3 Third Embodiment

3.1 Configuration of Optical Element

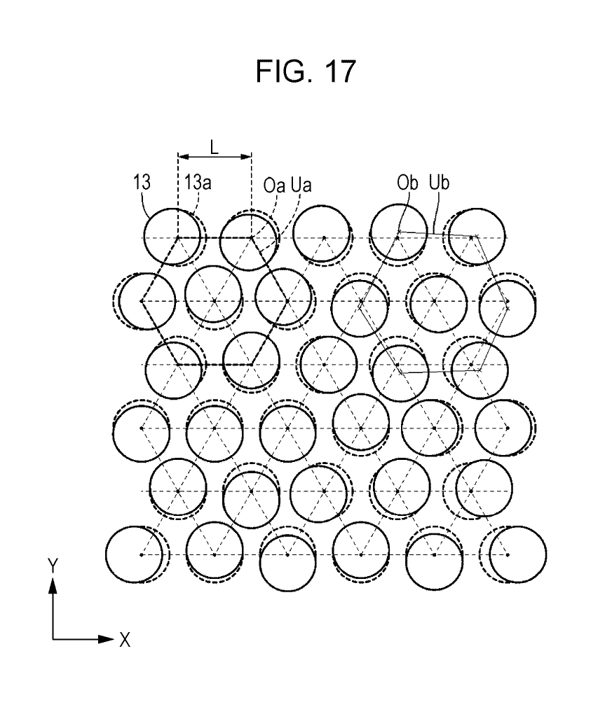

An optical element 11 according to the third embodiment of the present technology is different from the first embodiment, from the viewpoint that a hexagonal lattice Ua illustrated in FIG. 17 is used instead of the tetragonal lattice Ua illustrated in FIG. 4B. The plurality of structures 13 is disposed on each lattice point Ob of the distorted hexagonal lattice Ub, and the distortion direction of each distorted hexagonal lattice Ub is random.

3.2 Configuration of Reticle

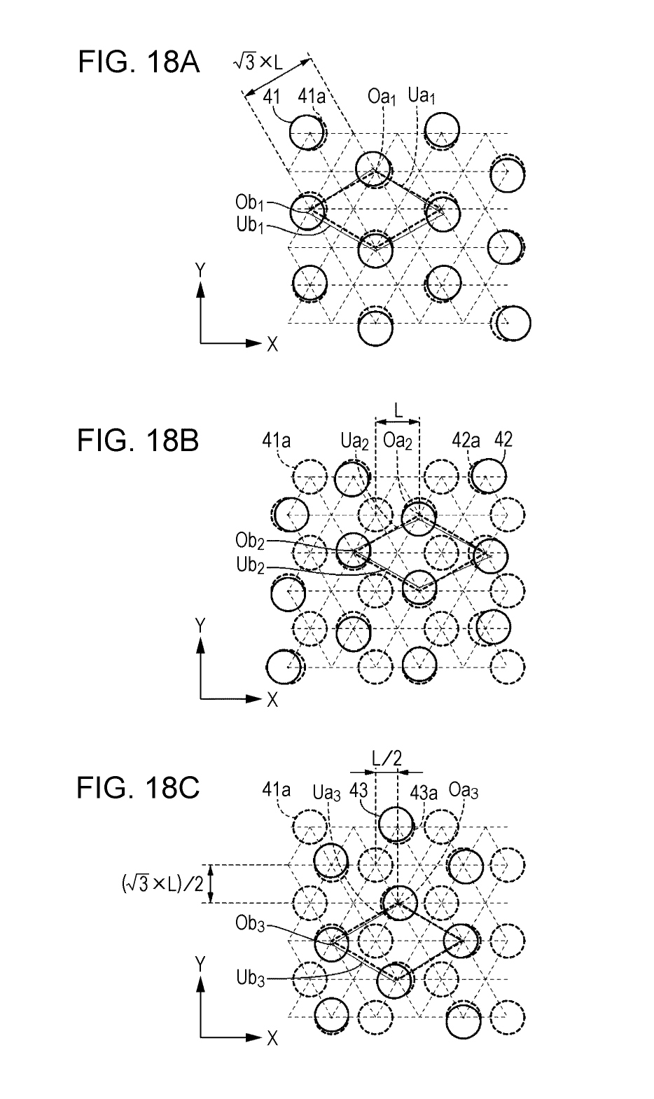

With reference to FIGS. 18A to 18C, an example of a configuration of a first to a third reticle will be described. Here, two directions orthogonal to each other on the surface of the first to the third reticle are referred to as the X-axis direction and the Y-axis direction, respectively.

First Reticle

As illustrated in FIG. 18A, the first reticle has a plurality of opening portions 41. The plurality of opening portions 41 is provided to be fluctuated in the random direction from the lattice point Oa₁ of the rhombic lattice Ua₁, at the interval which corresponds to substantially √3 times the lattice interval La of the optical element 11. In other words, the plurality of opening portions 41a is disposed on each lattice point Ob₁ of distorted rhombic lattice Ub₁, and the distortion direction of each distorted rhombic lattice Ub₁ is random. In addition, in FIG. 18A, the plurality of the opening portions 41a shown as a dashed line illustrates the plurality of virtual opening portions disposed on each lattice point Oa₁ of the rhombic lattice Ua₁ of which a length of one side is √3×L. Here, √3 represents a square root of 3.

Second Reticle

As illustrated in FIG. 18B, other than having a plurality of opening portions 42 provided to be fluctuated in the random direction from each lattice point Oa₂, the second reticle has the same configuration as the first reticle. The lattice point Oa₂ is the lattice point of the rhombic lattice Ua₂. The rhombic lattice Ua₂ is the rhombic lattice obtained by deviating each lattice point Oa₁ of the rhombic lattice Ua₁ by distance L in the X-axis direction.

Third Reticle

As illustrated in FIG. 18C, other than having a plurality of opening portions 43 provided to be fluctuated in the random direction from each lattice point Oa₃, the third reticle has the same configuration as the first reticle. The lattice point Oa₃ is the lattice point of the rhombic lattice Ua₃. The rhombic lattice Ua₃ is the rhombic lattice obtained by deviating each lattice point Oa₁ of the rhombic lattice Ua₁ by L/2 in the X-axis direction and by (√3×L)/2 in the Y-axis direction.

3.3 Manufacturing Method for Optical Element

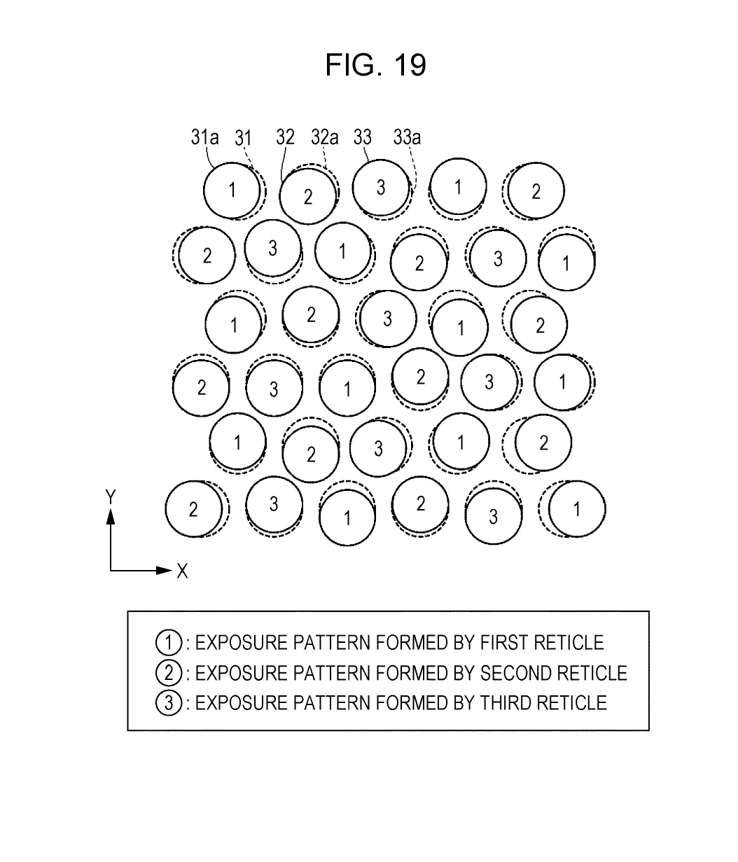

In a manufacturing method for the optical element 11 according to the third embodiment of the present technology, by using the first to the third reticle which have the above-described configuration, a plurality of exposure portions 31 to 33 is formed in the order from No. 1 to 3 described in FIG. 19. In other words, the plurality of exposure portions 31 to 33 is formed to be fluctuated in a random direction from a lattice point of the hexagonal lattice, at the interval which is equal to or shorter than the wavelength band of the light for reducing the reflection of the optical element 11. In other words, the plurality of exposure portions 31 to 33 is disposed on each lattice point of the distorted hexagonal lattice, and the distortion direction of each distorted hexagonal lattice is random.

### 4 Fourth Embodiment

4.1 Outline

In the fourth embodiment, an example in which the optical element according to any one of the above-described first to the third embodiments is employed in the capturing apparatus.

4.2 Configuration of Capturing Apparatus

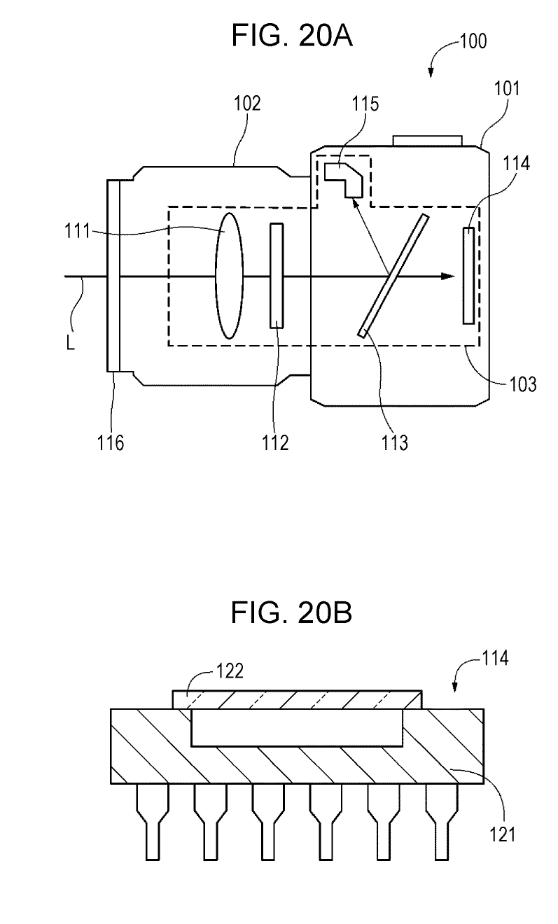

FIGS. 20A and 20B are schematic views illustrating an example of a configuration of the capturing apparatus according to the fourth embodiment of the present technology. As illustrated in FIGS. 20A and 20B, a capturing apparatus 100 according to the fourth embodiment is the so-called digital camera (digital still camera), and includes a housing 101, a lens barrel 102, a capturing optical system 103 provided inside the housing 101 and the lens barrel 102. The housing 101 and the lens barrel 102 may be configured to be detachable.

The capturing optical system 103 includes a lens 111, a light quantity adjusting device 112, a semi-transmissive mirror 113, a package (hereinafter, referred to as an “element package”) 114 of an image sensor element, and an autofocus sensor 115. The lens 111, the light quantity adjusting device 112, and the semi-transmissive mirror 113 are provided in order toward the element package 114 from a tip end of the lens barrel 102. At least one type of group selected from among the groups which consist of the lens 111, the light quantity adjusting device 112, the semi-transmissive mirror 113, and the element package 114 is given an anti-reflection function. The autofocus sensor 115 is provided at a position where the reflected light L can be received by the semi-transmissive mirror 113. The capturing apparatus 100 may be further provided with a filter 116 when necessary. When the filter 116 is provided, the filter 116 may be given the anti-reflection function. Hereinafter, each component and the anti-reflection function will be described in order.

Lens

The lens 111 concentrates the light L from a subject toward the element package 114.

Light Quantity Adjusting Device

The light quantity adjusting device 112 is a diaphragm device which adjusts a size of a diaphragm aperture which has an optical axis of the capturing optical system 103 as the center. The light quantity adjusting device 112 includes, for example, a pair of diaphragm blades and an ND filter which reduces a quantity of the transmitted light. As a driving method of the light quantity adjusting device 112, a method for driving the pair of diaphragm blades and the ND filter by one actuator and a method for driving the pair of diaphragm blades and the ND filter by two independent actuators respectively, can be used. However, the method is not limited thereto. As the ND filter, a filter having a uniform transmissivity or density or a filter having a transmissivity or density which is changed into gradations, can be used. In addition, the number of the ND filters is not limited to 1, and a plurality of ND filters can be stacked and used.

Semi-Transmissive Mirror

The semi-transmissive mirror 113 is a mirror which transmits a part of incident light and reflects a remainder of the incident light. More specifically, the semi-transmissive mirror 113 transmits the remainder of light L toward the element package 114, while a part of the light L concentrated by the lens 111 is reflected toward the autofocus sensor 115. A shape of the semi-transmissive mirror 113 can be a sheet shape or a plate shape, but the shape is not particularly limited thereto. Here, it is defined that a film is included in the sheet.

Element Package

The element package 114 receives the light transmitted from the semi-transmissive mirror 113, converts the received light into an electric signal, and outputs the signal to the signal processing circuit (not illustrated).

Here, with reference to FIG. 20B, an example of a configuration of the element package 114 will be described. The element package 114 includes an image sensor element 121 and a cover glass (cover body) 122 fixed to cover an opening window of the image sensor element 121. As the image sensor element 121, a charge coupled device (CCD) image sensor element or a complementary metal oxide semiconductor (COMS) image sensor element can be used.

Autofocus Sensor

The autofocus sensor 115 receives the light reflected by the semi-transmissive mirror 113, converts the received light into an electric signal, and outputs the signal to a control circuit (not illustrated).

Filter

The filter 116 is provided at the tip end of the lens barrel 102 or inside the capturing optical system 103. In addition, in FIG. 20A, an example in which the filter 116 is provided at the tip end of the lens barrel 102 is illustrated. When the configuration is employed, the filter 116 may be configured to be detachable with respect to the tip end of the lens barrel 102.

The filter 116 is generally provided at the tip end of the lens barrel 102 or inside the capturing optical system 103, but is not limited thereto. Examples of the filter 116 include a polarizing (PL) filter, a sharp cut (SC) filter, a filter for color enhancement and color effect, a neutral density (ND) filter, a light balancing (LB) filter, a color compensation (CC) filter, a filter for white balance acquisition, and a filter for lens protection.

Anti-Reflection Function

In the capturing apparatus 100, the light L from the subject transmits the plurality of optical elements (that is, the lens 111, the light quantity adjusting device 112, semi-transmissive mirror 113, and the cover glass 122) until the light reaches the image sensor element 121 from the tip end of the lens barrel 102. Hereinafter, the optical element, which is transmitted from the time when the light L from the subject is incorporated into the capturing apparatus 100 until the light reaches the image sensor element 121, is referred to as a “transmissive optical element”. When the capturing apparatus 100 is further provided with the filter 116, the filter 116 is also considered as one type of the transmissive optical element.

On a surface of at least one transmissive optical element among the plurality of transmissive optical elements, the plurality of structures 13 according to any one of the above-described first to the third embodiments is provided. Here, the surface of the transmissive optical element represents an incident surface on which the light L from the subject is incident, or an emission surface from which the incident light L from the incident surface is emitted. The plurality of structures 13 and the transmissive optical element may be separately molded, and may be integrally molded.

4.3 Effect

In the capturing apparatus according to the fourth embodiment, on a surface of at least one transmissive optical element among the plurality of transmissive optical elements, the plurality of structures 13 is provided at the interval which is equal to or shorter than the wavelength band of the light for reducing the reflection. Therefore, the surface of the transmissive optical element can be given the anti-reflection function, and the generation of ghosting or flare which is a cause of deterioration of image quality can be suppressed.

In addition, since the plurality of structures 13 is provided to be fluctuated in the random direction from the lattice point of the tetragonal lattice, the rectangular lattice, or the hexagonal lattice, the diffraction light can be scattered randomly. Therefore, it is possible to reduce the generation of ghosting which is seen in a spot shape. In other words, it is possible to further improve the image quality of the capturing apparatus 100.

### 5 Fifth Embodiment

5.1 Outline

In the above-described fourth embodiment, an example in which the present technology is employed to the digital camera (digital still camera) as the capturing apparatus is described, but the application example of the present technology is not limited thereto. In the fifth embodiment of the present technology, an example in which the present technology is employed to the digital video camera is described.

5.2 Configuration of Capturing Apparatus

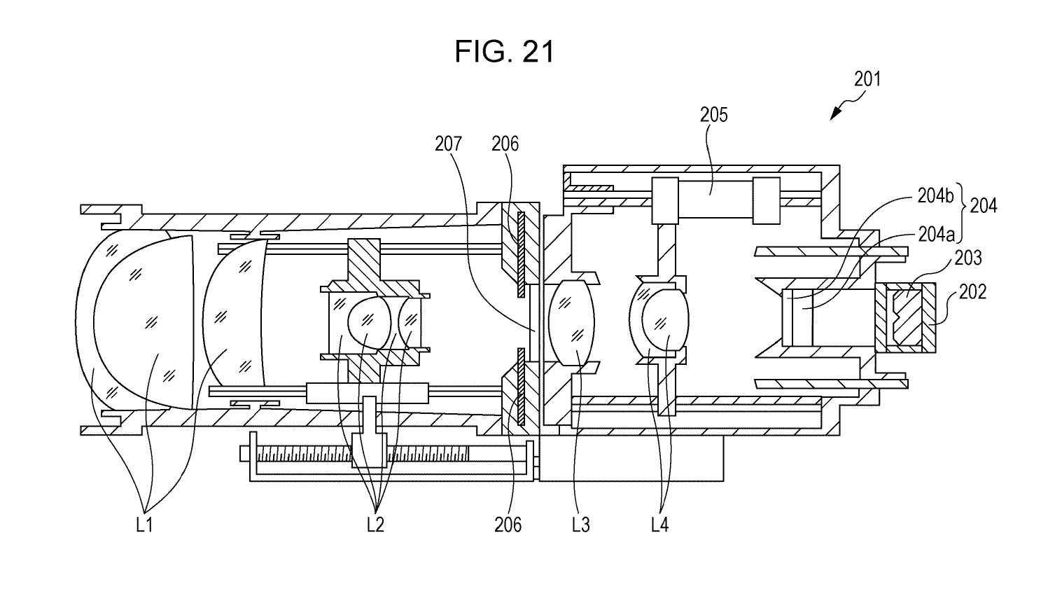

FIG. 21 is a schematic view illustrating an example of a configuration of the capturing apparatus according to the fifth embodiment of the present technology. As illustrated in FIG. 21, a capturing apparatus 201 according to the fifth embodiment is the so-called digital video camera, and includes a first lens group L1, a second lens group L2, a third lens group L3, a fourth lens group L4, an element package 202, a low pass filter 203, a filter 204, a motor 205, iris blades 206, and an electric dimmer element 207. In the capturing apparatus 201, the capturing optical system is configured to have the first lens group L1, the second lens group L2, the third lens group L3, the fourth lens group L4, the element package 202, the low pass filter 203, the filter 204, the iris blades 206, and the electric dimmer element 207. An optical adjusting device is configured to have the iris blades 206 and the electric dimmer element 207. Hereinafter, each component and the anti-reflection function will be described in order.

Lens Group

The first lens group L1 and the third lens group L3 are fixed lenses. The second lens group L2 is a zoom lens. The fourth lens group L4 is a focus lens.

Element Package

The element package 202 converts the incident light into the electric signal and supplies the signal to a signal processing portion (not illustrated). The element package 202 is the same as the element package 114 in the above-described fourth embodiment (refer to FIG. 19B).

Low Pass Filter

The low pass filter 203 is provided, for example, on a front surface of the element package 202, that is on the light incident surface of the cover glass 122. The low pass filter 203 suppresses a false signal (moire) which is generated when an image of a striped pattern close to an image element pitch or the like is captured. For example, the low pass filter 203 is configured to have artificial quartz.

The filter 204 cuts an infrared region of the light incident on the element package 202, suppresses floating of a spectrum in the infrared regions (630 nm to 700 nm), and makes light intensity of a visible band (400 nm to 700 nm) the same. The filter 204 is configured to have an infrared ray cut filter (hereinafter, referred to as an IR cut filter) 204a and an IR cut coat layer 204b formed by stacking an IR cut coat on the IR cut filter 204a. Here, the IR cut coat layer 204b is formed on at least one of a surface of a subject side of the IR cut filter 204a and a surface of the element package 202 side of the IR cut filter 204a. In FIG. 21, an example in which the IR cut coat layer 204b is formed on the surface of the subject side of the IR cut filter 204a is shown.

Based on a control signal supplied from a control portion (not illustrated), the motor 205 moves the fourth lens group L4. The iris blades 206 adjusts the quantity of the light incident on the element package 202, and is driven by a motor (not illustrated).

The electric dimmer element 207 adjusts the quantity of the light incident on the element package 202. The electric dimmer element 207 is an electric dimmer element made of a liquid crystal which has at least a dye-based pigment, for example, an electric dimmer element made of a dichroic GH liquid crystal.

Anti-Reflection Function

In the capturing apparatus 201, the light from the subject transmits the plurality of optical elements (the first lens group L1, the second lens group L2, the electric dimmer element 207, the third lens group L3, the fourth lens group L4, the filter 204, and the cover glass 122 having the low pass filter 203) until the light reaches the image sensor element 121. Hereinafter, the optical element, which is transmitted until the light L from the subject reaches the image sensor element 121, is referred to as a “transmissive optical element”. On a surface of at least one transmissive optical element among the plurality of transmissive optical elements, the plurality of structures 13 in any one of the above-described first to the third embodiments is provided.

5.3 Effect

In the fifth embodiment, in the digital video camera, it is possible to obtain the same effect as the above-described fourth embodiment.

### Example

Hereinafter, the present technology is described in detail by Embodiment, but the present technology is not limited only to Embodiment.

### Example 1

First, on a silicon wafer which is 8 inches, a photoresist was spin-coated. Four types of reticle of which the lattice interval is shortened two times were prepared so that the exposure pattern of a substantially tetragonal lattice having 250 nm of pitch on average on an image forming surface is formed by the four times of the multiple exposure (refer to FIGS. 9A to 9D). Each reticle was given different randomness. The exposure pattern of the substantially tetragonal lattice having 500 nm of pitch on average on an image forming surface was formed by each reticle. In addition, each reticle was given the randomness so that a respective structural position is substantially 50 nm at peak-to-peak (P-P) with respect to an ideal lattice position on the image forming surface. By using the reticles, in a stepper (reduction projection type exposure device) in which KrF (krypton fluoride) was NA=0.86, the reticles were switched and the exposure was performed.

A photoresist layer which performed pattern exposure was developed, and a plurality of photoresist patterns was formed on a substrate. After that, the etching process was performed by using the photoresist pattern as the mask, and a plurality of anti-reflection structures having 260 nm of depth was formed. Then, the photoresist pattern was removed and a Si original recording having the plurality of anti-reflection structures on the surface thereof was manufactured.

Next, after performing fluorine treatment on the surface of the original recording obtained as described above, by a transferring process using the original recording, the optical element was manufactured as described below. First, acrylic UV curable resin was spin-coated by 3 μm of thickness onto a glass substrate, the molding surface of the original recording was pushed against a resist-coated glass substrate, and then 2 MPa of pressure was pressed. Then, after curing by irradiation of the UV light of an Hg lamp with 2000 mJ/cm², the original recording was detached from the glass substrate, and then the plurality of anti-reflection structures obtained the optical element formed on the glass substrate.

### Comparative Example 1

Other than a case where the exposure pattern of a complete tetragonal lattice having 500 nm of pitch on average on the image forming surface by each reticle without giving the randomness to each reticle, the optical element was obtained similarly to Embodiment 1. In addition, in the KrF stepper used in the Embodiment, due to the positional accuracy error (alignment error) of the reticle, even in Comparative Example 1, the exposure pattern obtained by the four times of the multiple exposure was not the complete tetragonal lattice.

### Evaluation

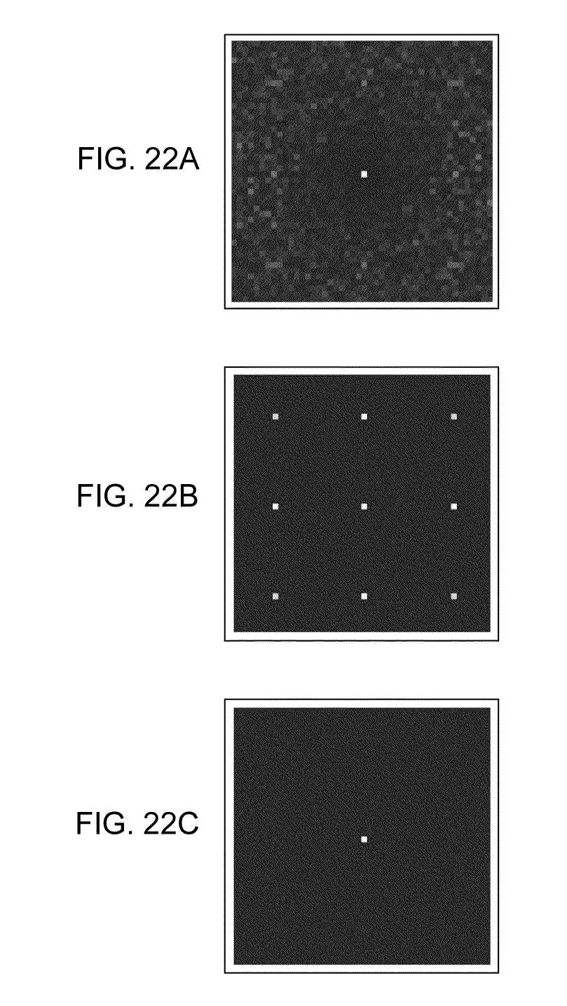

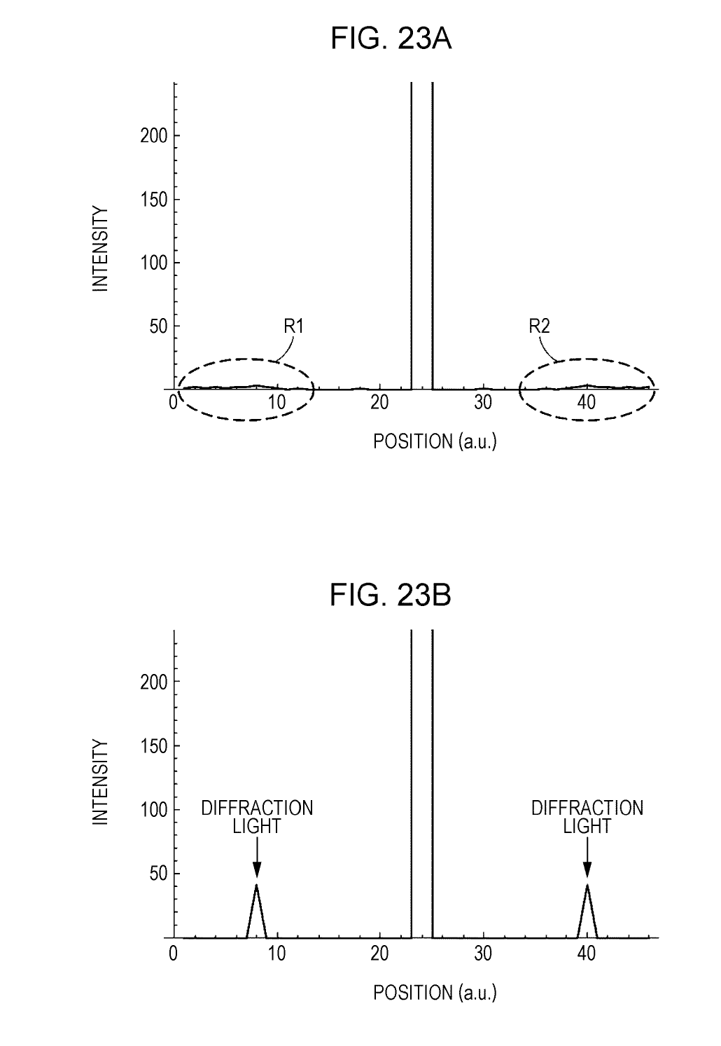

The optical element obtained as described above was disposed in front of the image sensor, and capturing a point light source was performed. The result thereof is illustrated in FIGS. 22A, 22B, 23A, and 23B. In addition, as described in Reference Example 1, the evaluation result of the ideal optical element, in which the plurality of structures is disposed in the complete tetragonal lattice shape, is illustrated in FIG. 22C.

Based on the above-described evaluation result, it was possible to find out the following.

In the optical element of Comparative Example 1, ±first-order diffraction light was generated. Meanwhile, in the optical element of Embodiment 1, the diffraction light was scattered, and the spot-shaped diffraction light was not clearly observed. In addition, in the ideal optical element, only the zero-order light was observed.

Similarly to the optical element of Embodiment 1, an irregular deviation optical element caused the plurality of different masks, each mask was deviated as much as the lattice interval, and the multiple exposure was performed. Accordingly, it was possible to reduce ghosting which was caused by randomly scattered diffraction light and was seen in a spot shape.

If the transmitted light in which the laser light source having 100 mW of 532 nm was transmitted to the optical element of Embodiment 1 was observed, a status in which the light originally scattered in the vicinity of the diffraction light position is present was seen. According to the optical element of Embodiment 1, the diffraction light is effectively scattered was found.

In the optical element of Comparative Example 1, a sharp peak intensity caused by ±first-order diffraction light was confirmed (refer to FIG. 23B). Meanwhile, in the optical element of Embodiment 1, it was possible to confirm that the peak intensity decreased and a full width at half maximum (FWMH) was widened.

In the above, the embodiments of the present technology are described in detail, but the present technology is not limited to the above-described embodiments. Based on the technical ideal of the present technology, it is possible to modify the technology in various ways.

For example, the configurations, the methods, the processes, the shapes, the materials, and the values in the above-described embodiments are merely examples. When necessary, different configurations, methods, processes, shapes, materials, and values may be used.

In addition, the configurations, the methods, the processes, the shapes, the materials, and the values in the above-described embodiments can be combined with each other without departing from the scope of the present technology.

In the above-described embodiment, an example is described in which each structure of the optical element has a protruded shape with respect to the base surface, but the present technology is not limited thereto. A configuration in which each structure of the optical element has a recessed shape with respect to the base surface may be employed. In this case, each structure of the original recording has a protruded shape with respect to the molding surface of the original recording.

In the above-described embodiment, a case where a lattice that constitutes the lattice point has a tetragonal, a rectangular, or a hexagonal lattice shape is described, but the shape of the lattice is not limited thereto. For example, an oblique lattice, a rhombic lattice, an oblong lattice, an isosceles triangular lattice, or a regular triangular lattice may be used.

In the above-described embodiment, a case where the plurality of structures on the optical element surface is provided to be fluctuated in the random direction from the lattice point is described, but the plurality of structures may be provided to be fluctuated randomly in one or more directions from the lattice point. Similarly, the plurality of opening portions in the reticles may be provided to be fluctuated in one or more directions from the lattice point.

In the present technology, by combining the exposure pattern of the plurality of masks, an exposure pattern in a distorted lattice shape, such as a distorted tetragonal lattice may be configured, a distorted rectangular lattice, or a distorted hexagonal lattice, and the number of the masks and the opening pattern of the masks is not limited to the example in the above-described embodiment.

In addition, the present technology can employ the following configuration.

(1) An optical element having a surface on which a plurality of structures is provided, in which the above-described plurality of structures is provided to be fluctuated in the random direction from the lattice point at the interval which is equal to or shorter than the wavelength of the visible light.

(2) The optical element described in (1) in which the above-described fluctuation range is equal to or less than a half of the distance between the adjacent lattice points.

(3) The optical element described in (1) or (2), in which the above-described lattice point is a lattice point of a tetragonal lattice, a rectangular lattice, or a hexagonal lattice.

(4) The optical element described in any of (1) to (3), in which the above-described plurality of structures has a protruded shape or a recessed shape with respect to the above-described surface.

(5) The optical element described in any of (1) to (4), in which the above-described plurality of structures is provided in a distorted shape of the tetragonal lattice, the rectangular lattice, or the hexagonal lattice, respectively.

(6) An optical system provided with the above-described optical element in any one of (1) to (5).

(7) A capturing apparatus provided with the above-described optical element in any one of (1) to (5).

(8) An optical equipment provided with the above-described optical element in any one of (1) to (5).

(9) An original recording having a surface on which a plurality of structures is provided, in which the plurality of structures is provided to be fluctuated in a random direction from a lattice point at an interval which is equal to or shorter than a wavelength of visible light.

(10) A manufacturing method for an original recording which includes: forming a plurality of exposure portions on a resist layer film-formed on the original recording, by using a plurality of masks in which a plurality of opening portions is provided to be fluctuated in a random direction from a lattice point; forming a resist pattern by developing the resist layer on which the plurality of the exposure portions is formed; and forming a surface on which the plurality of structures is provided at the interval which is equal to or shorter than the wavelength of the visible light, on the original recording, by performing an etching process with the resist pattern as the mask.

(11) The manufacturing method for an original recording described in (10) in which the above-described plurality of exposure portions is provided to be fluctuated in the random direction from the lattice point at the interval which is equal to or shorter than the visible light.

(12) The manufacturing method for an original recording described in (11) in which the fluctuation range of the above-described plurality of exposure portions is equal to or less than a half of the distance between the adjacent lattice points of the exposure portions.

(13) The manufacturing method for an original recording described in (11) or (12), in which a lattice point of the above-described exposure portion is a lattice point of a tetragonal lattice, a rectangular lattice, or a hexagonal lattice point.

(14) The manufacturing method for an original recording described in any one of (11) to (13), in which the above-described plurality of exposure portions is provided in a distorted shape of the tetragonal lattice, the rectangular lattice, or the hexagonal lattice, respectively.

(15) The manufacturing method for an original recording described in any one of (10) to (14), in which the lattice point of the above-described opening portion is the lattice point of the tetragonal lattice, the rectangular lattice, or the rhombic lattice.

(16) The manufacturing method for an original recording described in any one of (10) to (15), in which the above-described opening portion is provided in a distorted shape of the tetragonal lattice, the rectangular lattice, or the rhombic lattice, respectively.

(17) The manufacturing method for an original recording described in any one of (1) to (16), in which the plurality of structures has a protruded shape or a recessed shape with respect to the above-described surface.

(18) An optical element, in which the above-described structures are formed by a plurality of sub-structure alignments in a period longer than the most adjacent alignment, the position of each structure is irregularly deviated at a size smaller than the adjacent interval d with respect to a lattice center position in various sub-structure alignments, and the irregular arrangement between the sub-structure alignment are different, in the optical element which has an anti-reflection structure aligned regularly at the adjacent interval d which is equal to or shorter than the wavelength of the visible light.

(19) The optical element described in (17), in which the irregularly aligned anti-reflection structure is tiled and the irregularity of the various tiled components periodically appears for every tiling period.

(20) An optical element having a surface on which a plurality of structures is provided, in which the plurality of structures is provided to be fluctuated in one or more directions from a lattice point at an interval which is equal to or shorter than a wavelength of visible light.

(21) An original recording having a surface on which a plurality of structures is provided, in which the plurality of structures is provided to be fluctuated in one or more directions from a lattice point at an interval which is equal to or shorter than a wavelength of visible light.

(22) A manufacturing method for an original recording which includes: forming the plurality of exposure portions on the resist layer film-formed on the original recording, by using the plurality of masks in which the plurality of opening portions is provided to be fluctuated in one or more directions from the lattice point; forming a resist pattern by developing the resist layer on which the plurality of the exposure portions are formed; and forming the surface on which the plurality of structures is provided at the interval which is equal to or shorter than the wavelength of the visible light, on the original recording, by performing the etching process with the resist pattern as the mask.

It should be understood by those skilled in the art that various modifications, combinations, sub-combinations and alterations may occur depending on design requirements and other factors insofar as they are within the scope of the appended claims or the equivalents thereof.

What is claimed is:

1. An optical element, comprising:
a surface on which a plurality of structures is provided,
wherein the plurality of structures is provided to be fluctuated in a random direction from a lattice point at an interval which is equal to or shorter than a wavelength of visible light.

2. The optical element according to claim 1,
wherein the fluctuation range is equal to or less than half of a distance between adjacent lattice points.

3. The optical element according to claim 1,
wherein the lattice point is a lattice point of a tetragonal lattice, a rectangular lattice, or a hexagonal lattice.

4. The optical element according to claim 1,
wherein the plurality of structures has a protruded shape or a recessed shape with respect to the surface.

5. The optical element according to claim 1,
wherein the plurality of structures is provided in a distorted shape of the tetragonal lattice, the rectangular lattice, or the hexagonal lattice, respectively.

6. An optical system, comprising:
the optical element according to claim 1.

7. A capturing apparatus, comprising:
the optical element according to claim 1.

8. An optical equipment, comprising:
the optical element according to claim 1.

9. An original recording, comprising:
a surface on which a plurality of structures is provided,
wherein the plurality of structures is provided to be fluctuated in a random direction from a lattice point at an interval which is equal to or shorter than a wavelength of visible light.

10. A manufacturing method for an original recording, comprising:
forming a plurality of exposure portions on a resist layer film-formed on the original recording, by using a plurality of masks in which a plurality of opening portions is provided to be fluctuated in a random direction from a lattice point;
forming a resist pattern by developing the resist layer on which the plurality of the exposure portions is formed; and
forming a surface on which the plurality of structures is provided at the interval which is equal to or shorter than the wavelength of the visible light, on the original recording, by performing an etching process with the resist pattern as the mask.
